(19) United States
(12) Patent Application Publication
(10) Pub. No.: US 2025/0277680 A1
(43) Pub. Date: Sep. 4, 2025

(54) GRIP DETECTION DEVICE FOR STEERING WHEEL

(71) Applicant: Panasonic Automotive Systems Co., Ltd., Kanagawa (JP)

(72) Inventors: Tomonari IWATA, Osaka (JP); Hiroshi NAITOU, Osaka (JP); Takateru SAWADA, Osaka (JP)

(21) Appl. No.: 19/049,649

(22) Filed: Feb. 10, 2025

(30) Foreign Application Priority Data
Feb. 29, 2024 (JP) 2024-030176

(51) Int. Cl. G01D 5/24; B62D 1/04; H05B 3/06

(52) U.S. Cl. CPC G01D 5/24; B62D 1/046; H05B 3/06

(57) ABSTRACT

A grip detection device for a steering wheel includes: a first electrode arranged at a rim; a second electrode arranged at the rim; and a control circuit, in which the first electrode is wider in projected area than the second electrode, the control circuit allows switching between: a first mode in which the first electrode serves as a sensor electrode and the second electrode serves as a shield electrode; and a second mode in which the first electrode serves as the shield electrode and the second electrode serves as the sensor electrode, and the control circuit further: obtains a first-mode capacitance detected by the first electrode serving as the sensor electrode in the first mode and a second-mode capacitance detected by the second electrode serving as the sensor electrode in the second mode; and detects a grip on the steering wheel based on the first-mode capacitance and the second-mode capacitance.

### CROSS REFERENCE TO RELATED APPLICATION

The present application is based on and claims priority of Japanese Patent Application No. 2024-030176 filed on Feb. 29, 2024.

### FIELD

The present disclosure relates to a grip detection device for a steering wheel.

### BACKGROUND

PTL 1 discloses a sensor pad that includes a pad substrate, a sensor electrode, and a shield electrode. The sensor electrode and the shield electrode are spaced apart from and parallel to each other on a first surface of the pad substrate. The shield electrode is electrically coupled to a voltage source to create a capacitance between the shield electrode and the sensor electrode, and the sensor electrode can detect a change in the capacitance. The shield electrode can also heat the surface of a vehicle part. The sensor electrode can sense presence of an occupant's hands or body adjacent the steering wheel or seat assembly.

### CITATION LIST

### Patent Literature

PTL 1: International Publication No. WO2019/022765

### SUMMARY

However, the sensor pad according to PTL 1 can be improved upon.

In view of this, the present disclosure provides a grip detection device for a steering wheel that is capable of improving upon the above related art.

A grip detection device for a steering wheel according to one aspect of the present disclosure includes: a first electrode arranged at a rim of the steering wheel; a second electrode arranged at the rim and in a more inner layer of the steering wheel than the first electrode; and a control circuit, in which the first electrode is wider in projected area than the second electrode, the control circuit allows switching between: a first mode in which the first electrode serves as a sensor electrode and the second electrode serves as a shield electrode; and a second mode in which the first electrode serves as the shield electrode and the second electrode serves as the sensor electrode, and the control circuit further: obtains a first-mode capacitance detected by the first electrode serving as the sensor electrode in the first mode and a second-mode capacitance detected by the second electrode serving as the sensor electrode in the second mode; and detects a grip on the steering wheel based on the first-mode capacitance and the second-mode capacitance.

The grip detection device for the steering wheel according to the present disclosure is capable of improving upon the above related art.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1 illustrates a passenger compartment of a vehicle in which a steering wheel according to Embodiment 1 is disposed.

FIG. 2 is a perspective cross-sectional view of the steering wheel taken at line II-II in FIG. 1.

FIG. 3 is a circuit configuration of a grip detection device for a steering wheel according to Embodiment 1.

FIG. 4 is a diagram illustrating capacitances in cases where a first mode, a second mode, and a third mode are performed when a user's finger is touching the steering wheel.

FIG. 5 illustrates cases where each mode is driven in a time sharing manner.

### DESCRIPTION OF EMBODIMENT

Hereinafter, an embodiment is described in detail with reference to the drawings.

The embodiment described below presents a general or specific example. The numerical values, shapes, materials, elements, the arrangement and connection of the elements, etc., described in the following embodiment are mere examples, and therefore are not intended to limit the present disclosure. Accordingly, among elements in the following embodiment, those not appearing in any of the independent claims are described as optional elements.

The figures are schematic diagrams and are not necessarily precise illustrations. In the figures, like elements share like reference numbers.

In the following embodiments, expressions such as “T-shaped” are used. For example, “T-shaped” not only means exactly T-shaped, but also includes substantially T-shaped, i.e., includes an error of approximately several percent. In addition, “T-shaped” means T-shaped to an extent that the advantageous effects of the present disclosure can be achieved. The same applies to other expressions using “shaped”.

### Embodiment 1

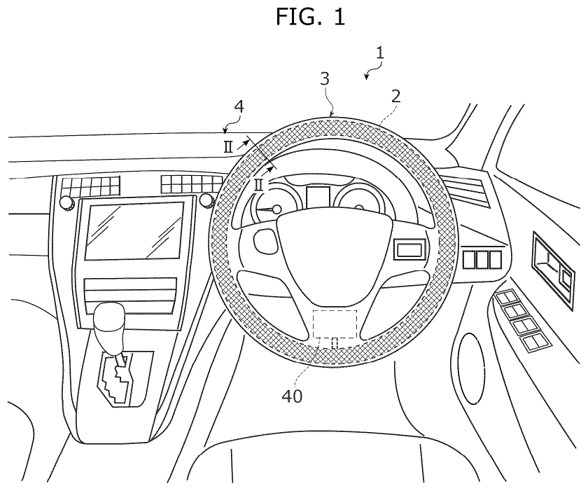

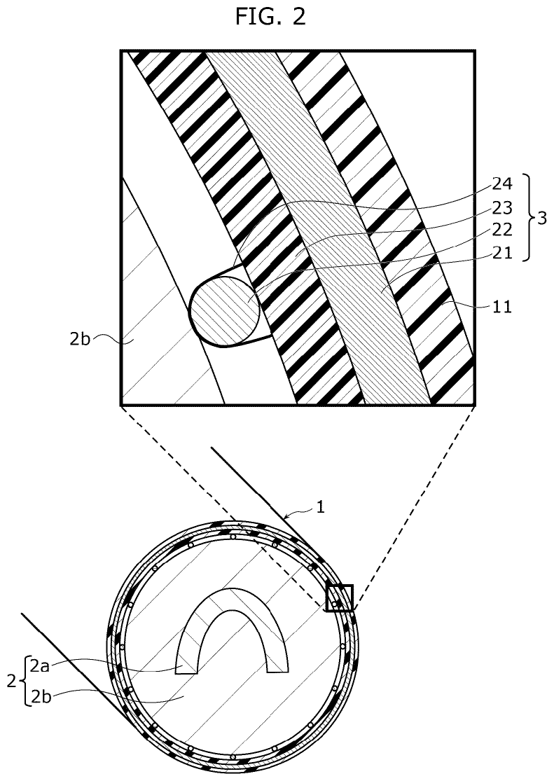

Firstly, the configuration of grip detection device for steering wheel 3 is described with reference to FIG. 1 and FIG. 2.

FIG. 1 illustrates a passenger compartment of vehicle 4 in which steering wheel 1 according to Embodiment 1 is disposed. FIG. 2 is a perspective cross-sectional view of steering wheel 1 taken at line II-II in FIG. 1.

As illustrated in FIG. 1 and FIG. 2, steering wheel 1 imparts a steering angle to, for example, the steering of vehicle 4.

Steering wheel 1 includes annular-shaped rim 2 and grip detection device for steering wheel 3. Rim 2 is integrally formed with a T-shaped spoke arranged on the inner circumferential surface of rim 2. Rim 2 is a grip part for gripping in driver's hand, and is ring-shaped.

Rim 2 includes core metal 2a which is an annular-shaped metal core, and resin layer 2b which covers core metal 2a. First electrode 21, second electrode 22, and base material 23 of grip detection device for steering wheel 3 are wrapped around rim 2. First electrode 21, second electrode 22, and base material 23 is described later. The outer circumference of first electrode 21 wrapped around rim 2 of grip detection device for steering wheel 3 is covered with steering cover 11 made of leather, a wood, a resin, etc. Steering cover 11 is adhered and fixed to the outer circumferential surface of first electrode 21 of grip detection device for steering wheel 3 with an adhesive, doubled-sided tape, or the like. Resin layer 2b is made of, for example, a urethane resin material such as foamed polyurethane.

Grip detection device for steering wheel 3 detects a touch of user's (person's) hand on steering wheel 1. The touch not only means a direct touch of user's hand on steering cover 11 of steering wheel 1, but also includes the state away from steering cover 11 as long as grip detection device for steering wheel 3 can sense user's hand. It is to be noted that grip detection device for steering wheel 3 can detect a tough even when, for example, user's arm or foot as well as hand touches steering wheel 1. In the present embodiment, the case where user's hand touches steering wheel 1 is described.

Grip detection device for steering wheel 3 is, for example, a capacitance-type proximity sensor, and is also a grip sensor that detects a grip with the hand of a user in vehicle 4 with steering wheel 1. Specifically, grip detection device for steering wheel 3 senses a change in capacitance between the user's hand and first electrode 21 of grip detection device for steering wheel 3, thereby detecting whether the user's hand is touching steering wheel 1. When the user's hand is away from steering wheel 1, grip detection device for steering wheel 3 detects the capacitance between vehicle 4 and first electrode 21. However, the distance between vehicle 4 and first electrode 21 is extremely larger than the distance between first electrode 21 and the user's hand when the user's hand comes close to or is touching steering cover 11, and thus the capacitance between vehicle 4 and first electrode 21 is minimal. Moreover, when the user's hand comes close to or is touching steering cover 11, the capacitance changes since the user's hand intervenes between first electrode 21 and the vehicle body. When the sensed capacitance is greater than or equal to a defined value, it can be determined that the user's hand is touching or gripping steering wheel 1.

Grip detection device for steering wheel 3 includes first electrode 21, base material 23, sewing thread 24, second electrode 22, control circuit 40, and power supply circuit 40c.

First electrode 21 is arranged around rim 2 of steering wheel 1. Specifically, first electrode 21 is arranged on the inner surface of steering cover 11 and the outer surface of base material 23. In other words, first electrode 21 is sandwiched between steering cover 11 and base material 23. The outer surface of base material 23 faces steering cover 11. First electrode 21 is fixed to base material 23 by adhering to the inner surface of steering cover 11 with an adhesive layer (not illustrated), and to the outer surface of base material 23 with an adhesive layer (not illustrated). First electrode 21 is connected to control circuit 40.

It is to be noted that only one first electrode 21 may be arranged on the outer surface of base material 23, or multiple first electrodes 21 may be arranged on the outer surface of base material 23.

First electrode 21 is wider in projected area than second electrode 22. As described later, second electrode 22 is a heater wire made of a conductive wire, and thus first electrode 21 is wider than second electrode 22 in the projected area when first electrode 21 and second electrode 22 are overlapped and viewed.

First electrode 21 is, for example, a solid electrode with a planar structure of a conductor, or a conductive fabric manufactured by applying plating to a non-metallic fiber. The non-metallic fiber is polyethylene terephthalate (PET) or the like. The plating is, for example, copper plating and nickel plating layered on the copper plating.

Base material 23 is a non-woven fabric of an elastic, flexible, and ductile material formed into an elongated sheet-like shape. For example, base material 23 is made of a synthetic resin such as polyethylene (PE) or polyethylene terephthalate (PET).

Base material 23 has an outer surface and an inner surface. First electrode 21 is arranged on the outer surface with an adhesive layer (not illustrated) interposed therebetween, and second electrode 22 is arranged on the inner surface with an adhesive layer (not illustrated) interposed therebetween. In other words, base material 23 is sandwiched between first electrode 21 and second electrode 22. The inner surface is a surface holding second electrode 22 and facing rim 2.

First electrode 21, second electrode 22, and base material 23 of grip detection device for steering wheel 3 are wrapped around rim 2, and thus base material 23 is attached to rim 2. Base material 23 is elongated (strip-shaped) such that rim 2 can be totally covered by wrapping base material 23 around rim 2 in the wrapping direction and also in a direction perpendicular to the wrapping direction when first electrode 21, second electrode 22, and base material 23 of grip detection device for steering wheel 3 are wrapped around rim 2. In other words, base material 23 is formed in accordance with the shape and the size of rim 2.

Second electrode 22 is a heater wire made of a conductive wire. Second electrode 22 is arranged around rim 2. Specifically, second electrode 22 is arranged in a more inner layer of steering wheel 1 than first electrode 21, i.e., closer to rim 2 than first electrode 21 is. One end of second electrode 22 and the other end of second electrode 22 are connected to control circuit 40. Second electrode 22 is arranged on the inner surface of base material 23 in a winding (zig-zag) manner. Specifically, second electrode 22 is, for example, a metal wire such as a copper wire, and is sewed onto the inner surface of base material 23 with sewing thread 24 to form into a winding pattern. Here, “second electrode 22 is sewed onto the inner surface of base material 23 with sewing thread 24” means a state in which second electrode 22 is fastened to base material 23 by sewing thread 24 stitched on base material 23.

It is to be noted that second electrode 22 according to the present embodiment is sewed onto the back of base material 23 with sewing thread 24, but may be fixed to base material 23 using thermocompression bonding or the like. Moreover, second electrode 22 may be fixed to base material 23 using an adhesive.

Second electrode 22 is arranged on the surface of rim 2, and is adhered to the surface of rim 2 with an adhesive (not illustrated). Second electrode 22 is sandwiched between rim 2 and base material 23.

Control circuit 40 is embedded in, for example, a spoke. Control circuit 40 is electrically connected to first electrode 21 and second electrode 22, and detects a touch on steering wheel 1 based on a signal transmitted from first electrode when user's hand comes close to steering wheel 1. In other words, control circuit 40 detects whether user's hand is touching rim 2.

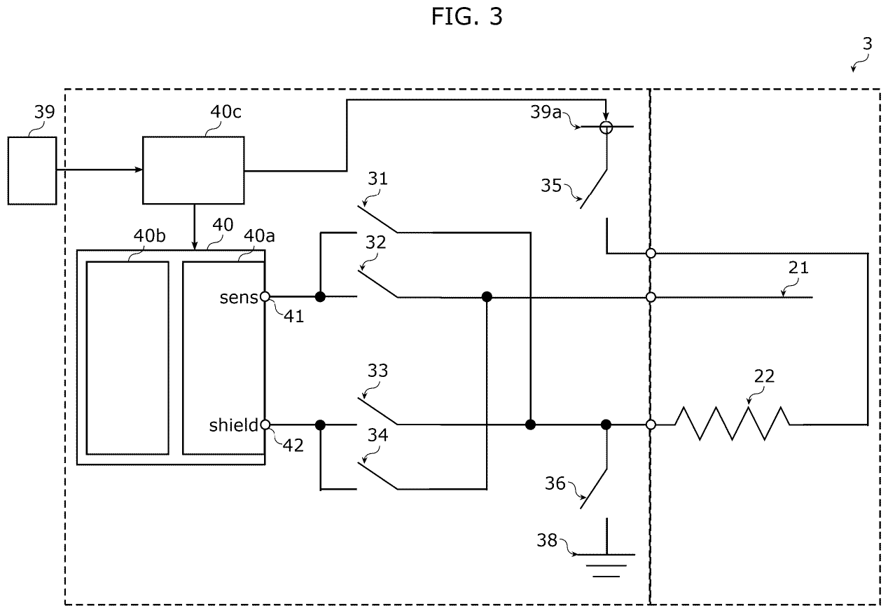

Control circuit 40 is electrically connected to power supply circuit 40c. By controlling power supply circuit 40c, control circuit 40 supplies power from battery 39 to first electrode 21 and second electrode 22 in detecting whether the user's hand is touching rim 2, or supplies power from battery 39 to second electrode 22 to generate the heat of second electrode 22. In other words, power supply circuit 40c is controlled by control circuit 40 to apply a measurement voltage to first electrode 21 and second electrode 22. Moreover, power supply circuit 40c is controlled by control circuit 40 to pass direct current through second electrode 22. Second electrode 22 functions as a heater by the direct current passing through second electrode 22. In this case, the direct current just passes through second electrode 22, and thus as illustrated in FIG. 3 described later, one end of second electrode 22 and the other end of second electrode 22 are electrically connected to battery terminal 39a and ground 38, respectively. It is to be noted that second electrode 22 is not limited to the configuration including the heating function. Second electrode 22 may have a configuration of only floating from ground 38 without passing the direct current through second electrode 22.

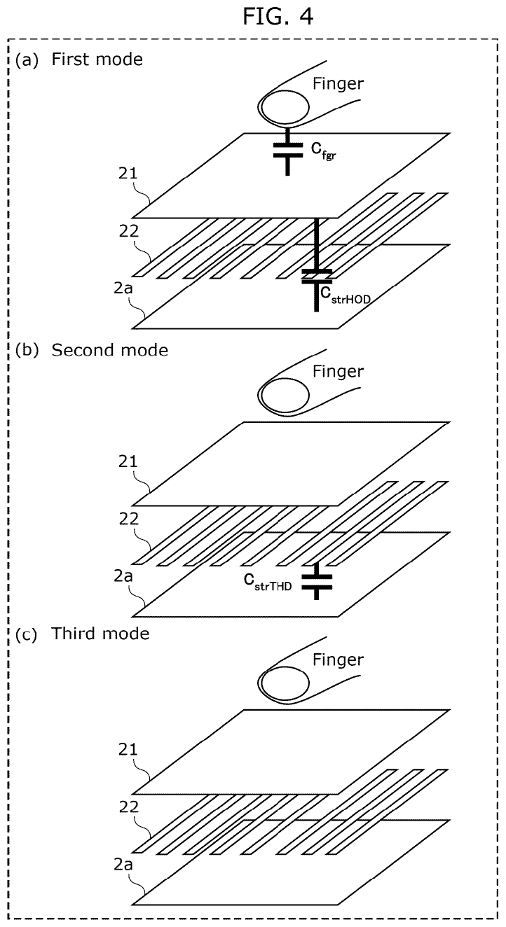

Next, the circuit configuration and the function of grip detection device for steering wheel 3 are described with reference to FIG. 3 and FIG. 4.

FIG. 3 is the circuit configuration of grip detection device for steering wheel 3 according to Embodiment 1. FIG. 4 is a diagram illustrating capacitances in cases where a first mode, a second mode, and a third mode are performed when user's hand is touching steering wheel 1. Part (a) of FIG. 4 illustrates capacitance C_{fgr} and capacitance C_{strHOD} measured when user's hand is touching steering wheel 1 in the first mode. Part (b) of FIG. 4 illustrates capacitance C_{strTHD} measured when user's hand is touching steering wheel 1 in the second mode. Part (c) of FIG. 4 illustrates no capacitance measured when user's hand is touching steering wheel 1 in the third mode.

As shown in FIG. 3, control circuit 40 has the following modes: the first mode in which first electrode 21 serves as a sensor electrode and second electrode 22 serves as a shield electrode; and the second mode in which first electrode 21 serves as a shield electrode and second electrode 22 serves as a sensor electrode. Control circuit 40 allows switching between the first mode and the second mode. In this case, control circuit 40 can detect a grip on steering wheel 1 based on the obtained first-mode capacitance and second-mode capacitance.

Control circuit 40 further has the third mode in which second electrode 22 acts as a heater. Control circuit 40 also allows switching among the first mode, the second mode, and the third mode. In this case, control circuit 40 can generate the heat of second electrode 22 by supplying power to second electrode 22, as well as detect a grip on steering wheel 1 based on the obtained first-mode capacitance and second-mode capacitance.

Control circuit 40 has capacitance sensor circuit 40a.

Capacitance sensor circuit 40a calculates the capacitance between first electrode 21 and user's hand to detect a touch of the user's hand on steering wheel 1, thereby detecting a grip on steering wheel 1 with the user's hand.

Capacitance sensor circuit 40a has sensor terminal 41 and shield terminal 42.

Sensor terminal 41 can apply the measurement voltage to the electrode connected to sensor terminal 41, and thus allows the connected electrode to serve as a sensor electrode. Specifically, sensor terminal 41 allows first electrode 21 to serve as the sensor electrode in the first mode and second electrode 22 to serve as the sensor electrode in the second mode.

Shield terminal 42 can apply a shield voltage with the same phase as the measurement voltage to the electrode connected to shield terminal 42, and thus allows the connected electrode to serve as a shield electrode. Specifically, shield terminal 42 allows second electrode 22 to serve as the shield electrode in the first mode and first electrode 21 to serve as the shield electrode in the second mode.

Grip detection device for steering wheel 3 includes first switch 31, second switch 32, third switch 33, fourth switch 34, fifth switch 35, and sixth switch 36, as well as control circuit 40, power supply circuit 40c, first electrode 21, and second electrode 22.

First switch 31 is arranged between sensor terminal 41 and second electrode 22. Specifically, first switch 31 has: one end connected to sensor terminal 41 and one end of second switch 32; and the other end connected to one end of sixth switch 36, the other end of third switch 33, and one end of second electrode 22.

Second switch 32 is arranged between sensor terminal 41 and first electrode 21. Specifically, second switch 32 has: one end connected to sensor terminal 41 and one end of first switch 31; and the other end connected to the other end of fourth switch 34 and one end of first electrode 21.

Third switch 33 is arranged between shield terminal 42 and second electrode 22. Specifically, third switch 33 has: one end connected to shield terminal 42 and one end of fourth switch 34; and the other end connected to the other end of first switch 31, one end of sixth switch 36, and one end of second electrode 22.

Fourth switch 34 is arranged between shield terminal 42 and first electrode 21. Specifically, fourth switch 34 has: one end connected to shield terminal 42 and one end of third switch 33; and the other end connected to the other end of second switch 32 and one end of first electrode 21.

Fifth switch 35 is arranged between battery terminal 39a and the other end of second electrode 22. Specifically, fifth switch 35 has: one end connected to the other end of second electrode 22; and the other end connected to power supply circuit 40c for supplying power from battery 39.

Sixth switch 36 is arranged between ground 38 and one end of second electrode 22. Specifically, sixth switch 36 has: one end connected to the other end of first switch 31, the other end of third switch 33, and one end of second electrode 22; and the other end connected to ground 38.

Control circuit 40 further has mode switching circuit 40b.

Mode switching circuit 40b can control switching for each of first switch 31, second switch 32, third switch 33, fourth switch 34, fifth switch 35, and sixth switch 36. Accordingly, mode switching circuit 40b can switch modes including the first mode and the second mode at predetermined intervals. Mode switching circuit 40b also can switch modes including the first mode, the second mode, and the third mode at predetermined intervals.

In such a circuit configuration, in the first mode, mode switching circuit 40b can turn on second switch 32 and third switch 33 and turn off the other switches (first switch 31, fourth switch 34, fifth switch 35, and sixth switch 36).

In the second mode, mode switching circuit 40b can turn on first switch 31 and fourth switch 34 and turn off the other switches (second switch 32, third switch 33, fifth switch 35, and sixth switch 36).

In the third mode, mode switching circuit 40b can turn on fifth switch 35 and sixth switch 36 and turn off the other switches (first switch 31, second switch 32, third switch 33, and fourth switch 34).

Next, the operation of grip detection device for steering wheel 3 is described with reference to FIG. 3 through FIG. 5.

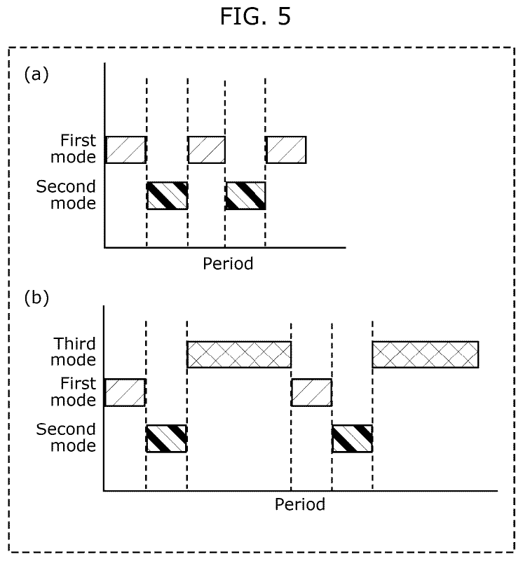

FIG. 5 illustrates cases where each mode is driven in a time sharing manner. Part (a) of FIG. 5 illustrates a case of switching between the first mode and the second mode. Part (b) of FIG. 5 illustrates a case of switching among the first mode, the second mode, and the third mode. In parts (a) and (b) of FIG. 5, a period during which the first mode is performed is indicated by positive diagonal hatching, a period during which the second mode is performed is indicated by negative diagonal hatching, and a period during which the third mode is performed is indicated by crosshatching.

Capacitance sensor circuit 40a can obtain the first-mode capacitance detected by first electrode 21 serving as the sensor electrode in the first mode and the second-mode capacitance detected by second electrode 22 serving as the sensor electrode in the second mode, and detect a grip on steering wheel 1 with user's hand based on the first-mode capacitance and the second-mode capacitance.

As illustrated in part (a) of FIG. 5, when the third mode is not performed, grip detection device for steering wheel 3 can repeatedly switch between the first mode and the second mode at predetermined intervals.

Specifically, as illustrated in FIG. 3 and FIG. 4, mode switching circuit 40b turns on second switch 32 and third switch 33 and turns off the other switches to drive control circuit 40 in the first mode. In the first mode, capacitance sensor circuit 40a passes alternating current through first electrode 21, i.e., applies the measurement voltage to first electrode 21. In this mode, when user's hand touches steering cover 11 of rim 2, the capacitance of first electrode 21 corresponding to the touched portion changes. Accordingly, sensor terminal 41 of capacitance sensor circuit 40a measures the capacitance of first electrode 21 based on the value of the current passing through first electrode 21 (the measurement voltage). In the equivalent circuit, as illustrated in part (a) of FIG. 4, capacitance C_{fgr} and capacitance C_{strHOD} are connected in parallel with respect to first electrode 21 connected to capacitance sensor circuit 40a. The capacitance measured in the first mode (the first-mode capacitance) includes capacitance C_{fgr} between the hand and first electrode 21 and capacitance C_{strHOD} between first electrode 21 and core metal 2a. Capacitance C_{fgr} indicates a sensor value between the hand and first electrode 21. Capacitance C_{strHOD} indicates the parasitic capacitance within steering wheel 1. It is to be noted that “HOD” is the abbreviation for Hands On Detection.

After a predetermined period sufficient to measure the capacitance in the first mode has elapsed, mode switching circuit 40b switches the mode from the first mode to the second mode. Specifically, mode switching circuit 40b turns on first switch 31 and fourth switch 34 and turns off the other switches to drive control circuit 40 in the second mode. In the second mode, capacitance sensor circuit 40a passes alternating current through second electrode 22, i.e., applies the measurement voltage to second electrode 22. In this mode, even when user's hand is touching steering cover 11, the capacitance between the user's hand and first electrode 21 cannot be measured since second switch 32 is off, and the capacitance between the user's hand and second electrode 22 also cannot be measured since first electrode 21 intervenes between the user's hand and second electrode 22 as the shield electrode. Sensor terminal 41 of capacitance sensor circuit 40a measures the capacitance of second electrode 22 based on the value of current passing through second electrode 22 (the measurement value). The capacitance measured in the second mode (the second-mode capacitance) is capacitance C_{strTHD} between second electrode 22 and core metal 2a. Capacitance C_{strTHD} indicates the parasitic capacitance within steering wheel 1. It is to be noted that “THD” is the abbreviation for Temperature & Humidity Detection.

Capacitance C_{strHOD} and capacitance C_{strTHD} are coupled within steering wheel 1, and thus vary depending on a change in external environment such as temperature and humidity. However, it is known that there is a correlation in the capacitance variation depending on the change in external environment. For example, the capacitance is 50 pF under conditions where the ambient temperature is 25 degrees C. and the humidity is 30%, but the capacitance is 150 pF under conditions where the ambient temperature is 40 degrees C. and the humidity is 95%. This property can be used to estimate and calculate capacitance C_{strHOD} from capacitance C_{strTHD}.

When a function of the correlation, i.e., capacitance C_{strHOD}=f(capacitance C_{strTHD}), is obtained in advance, capacitance sensor circuit 40a can calculate C_{strHOD} based on C_{strTHD} measured in the second mode, using the above function representing the correlation. After calculating C_{strHOD}, capacitance sensor circuit 40a can calculate capacitance C_{fgr} by subtracting calculated capacitance C_{strHOD} from the first-mode capacitance measured in the first mode (capacitance C_{fgr}+capacitance C_{strHOD}). Based on calculated capacitance C_{fgr}, capacitance sensor circuit 40a can detect that user's hand has gripped steering wheel 1.

It is to be noted that the period (the predetermined period) during which the first mode is performed and the period (the predetermined period) during which the second mode is performed are equal to each other. For example, the period during which the first mode is performed and the period during which the second mode is performed are each several milliseconds.

Accordingly, mode switching circuit 40b switches modes including the first mode and the second mode at predetermined intervals, i.e., drives the modes in a time sharing manner, and thus grip detection device for steering wheel 3 can detect that user's hand has gripped steering wheel 1.

As illustrated in part (b) of FIG. 5, in grip detection device for steering wheel 3, mode switching circuit 40b also can repeatedly switch modes including the first mode, the second mode, and the third mode at predetermined intervals. For example, mode switching circuit 40b may perform the third mode after performing the first mode and the second mode.

Specifically, when a predetermined period has elapsed after performing the second mode, mode switching circuit 40b switches the mode from the second mode to the third mode. Specifically, mode switching circuit 40b turns on fifth switch 35 and sixth switch 36 and turns off the other switches to drive control circuit 40 in the third mode. In the third mode, capacitance sensor circuit 40a passes direct current through second electrode 22 to cause second electrode 22 to function as a heater. In other words, second electrode 22 is electrically connected to battery 39 that supplies power to one end of second electrode 22, thereby acting as a heater. In this case, sixth switch 36 is turned on, and thus the direct current flows into ground 38 after passing through second electrode 22. In this mode, even when user's hand is touching steering cover 11, the capacitance between the user's hand and first electrode 21 cannot be measured since second switch 32 is off. The capacitance between second electrode 22 and core metal 2a also cannot be measured since first switch 31 is off.

In a period during which the third mode is performed, grip detection device for steering wheel 3 can heat steering wheel 1 by generating the heat of second electrode 22.

The period during which the third mode is performed is longer than the period during which the first mode is performed and the period during which the second mode is performed. For example, the period during which the third mode is performed is at least several tens of milliseconds. Accordingly, it is possible to detect that user's hand has gripped steering wheel 1, without losing the ability to increase temperature and the ability to keep warmth of steering wheel 1.

### Advantageous Effects

Next, the advantageous effects of grip detection device for steering wheel 3 according to the present embodiment are described.

For example, in conventional techniques, in the case where a heater pattern whose projected area is smaller than that of a sensor electrode is used as a shield electrode, when the heater pattern is arranged parallel to the sensor electrode, the parasitic capacitance between the sensor electrode and a core metal (a component for the GND potential) that is present inside a steering wheel is increased. In sensing a grip on the steering wheel, a signal in which the parasitic capacitance is added to a sensor value of the grip sensing is detected. The parasitic capacitance always varies depending on the external environment such as temperature and humidity, and thus the detected signal value also varies. Accordingly, this variation causes false sensing results.

In view of this, as described above, grip detection device for steering wheel 3 according to Technique 1 of the present embodiment includes: first electrode 21 arranged at rim 2 of steering wheel 1; second electrode 22 arranged at rim 2 and in a more inner layer of steering wheel 1 than first electrode 21; and control circuit 40, in which first electrode 21 is wider in projected area than second electrode 22, control circuit 40 allows switching between: a first mode in which first electrode 21 serves as a sensor electrode and second electrode 22 serves as a shield electrode; and a second mode in which first electrode 21 serves as the shield electrode and second electrode 22 serves as the sensor electrode, and control circuit 40 further: obtains a first-mode capacitance detected by first electrode 21 serving as the sensor electrode in the first mode and a second-mode capacitance detected by second electrode 22 serving as the sensor electrode in the second mode; and detects a grip on steering wheel 1 based on the first-mode capacitance and the second-mode capacitance.

With this, capacitance C_{strHOD} can be calculated based on capacitance C_{strTHD} indicated by the second-mode capacitance, and thus capacitance sensor circuit 40a can calculate capacitance C_{fgr} by subtracting calculated capacitance C_{strHOD} from the first-mode capacitance (capacitance C_{fgr}+capacitance C_{strHOD}).

Therefore, according to the present disclosure, it is possible to prevent the reduction in robustness of grip sensing and to achieve highly-accurate grip sensing.

In particular, in the conventional grip detection device for steering wheel, the third electrode serving as the shield electrode is further arranged between the first electrode which serves as the sensor electrode and the second electrode which performs the heating function. However, grip detection device for steering wheel 3 according to the present embodiment is configured to detect a grip on steering wheel 1 by switching between the first mode and the second mode, and thus it is not necessary to further arrange the third electrode serving as the shield electrode in the steering wheel like the conventional grip detection device for steering wheel. Accordingly, grip detection device for steering wheel 3 according to the present disclosure can prevent an increase in the number of components and also prevent an increase in manufacturing cost of grip detection device for steering wheel 3.

Moreover, grip detection device for steering wheel 3 according to Technique 2 of the present embodiment is grip detection device for steering wheel 3 according to Technique 1, in which control circuit 40 includes capacitance sensor circuit 40a having: sensor terminal 41 that allows first electrode 21 to serve as the sensor electrode in the first mode and second electrode 22 to serve as the sensor electrode in the second mode; and shield terminal 42 that allows second electrode 22 to serve as the shield electrode in the first mode and first electrode 21 to serve as the shield electrode in the second mode, the grip detection device further includes: first switch 31 arranged between sensor terminal 41 and second electrode 22; second switch 32 arranged between sensor terminal 41 and first electrode 21; third switch 33 arranged between shield terminal 42 and second electrode 22; and fourth switch 34 arranged between shield terminal 42 and first electrode 21, and control circuit 40: turns on second switch 32 and third switch 33 and turns off remaining switches in the first mode; and turns on first switch 31 and fourth switch 34 and turns off remaining switches in the second mode.

With this, it is possible to switch between the first mode and the second mode by controlling first switch 31, second switch 32, third switch 33, and fourth switch 34. Accordingly, it is possible to detect a grip on steering wheel 1 based on the first-mode capacitance and the second-mode capacitance.

Moreover, grip detection device for steering wheel 3 according to Technique 3 of the present embodiment is grip detection device for steering wheel 3 according to Technique 1 or 2, in which control circuit 40 further allows switching to a third mode in which second electrode 22 acts as a heater.

With this, second electrode 22 can act as a heater by performing the third mode. Accordingly, it is possible to simultaneously implement, using second electrode 22, the heating function of heating steering wheel 1 and the function of detecting a grip on steering wheel 1 with user's hand.

Moreover, grip detection device for steering wheel 3 according to Technique 4 of the present embodiment is grip detection device for steering wheel 3 according to Technique 3, in which second electrode 22, when acting as the heater, is connected to battery 39 that supplies power to a first end of second electrode 22, a second end of second electrode 22 is connectable to ground 38, the grip detection device further includes: fifth switch 35 arranged between battery 39 and the first end of second electrode 22; and sixth switch 36 arranged between ground 38 and the second end of second electrode 22, and control circuit 40 turns on fifth switch 35 and sixth switch 36 and turns off remaining switches in the third mode.

With this, in the third mode, power from battery 39 can be supplied to second electrode 22, and thus it is possible to generate the heat of second electrode 22 to fulfill the heating function of heating steering wheel 1.

Moreover, grip detection device for steering wheel 3 according to Technique 5 of the present embodiment is grip detection device for steering wheel 3 according to any one of Techniques 1 to 4, in which control circuit 40 includes mode switching circuit 40b that switches modes including the first mode and the second mode at predetermined intervals.

With this, it is possible to accurately detect the case where user's hand has gripped steering wheel 1 and the case where user's hand is away from steering wheel 1, by switching between the first mode and the second mode at predetermined intervals.

Moreover, grip detection device for steering wheel 3 according to Technique 6 of the present embodiment is grip detection device for steering wheel 3 according to Technique 3 or 4, in which control circuit 40 includes mode switching circuit 40b that switches modes including the first mode, the second mode, and the third mode at predetermined intervals.

With this, it is possible to accurately detect, while heating steering wheel 1 using second electrode 22, the case where user's hand has gripped steering wheel 1 and the case where user's hand is away from steering wheel 1, by switching among the first mode, the second mode, and the third mode at predetermined intervals.

### Other Embodiments

Although the grip detection device for steering wheel according to the present disclosure has been described based on the above embodiment, the present disclosure is not limited to the embodiment. Embodiments achieved by applying various modifications to the above embodiment conceived by a person skilled in the art without departing from the spirit of the present disclosure are also included in the present disclosure.

For example, grip detection device for steering wheel 3 according to the present disclosure may include multiple first electrodes 21 or multiple second electrodes 22. Moreover, grip detection device for steering wheel 3 may include one first electrode 21 and multiple second electrodes 22, or multiple first electrodes 21 and one second electrode 22. Also in these cases, control circuit 40 may switch modes including the first mode and the second mode at predetermined intervals, or modes including the first mode, the second mode, and the third mode at predetermine intervals.

Moreover, multiple grip detection devices for steering wheel 3 according to the present disclosure may be independently arranged in steering wheel 1. For example, when steering wheel 1 is in the right position (the steering angle is 0°), grip detection device for steering wheel 3 may be arranged on each of the left side and the right side. It should be appreciated that three or more grip detection devices for steering wheel 3 may be arranged in steering wheel 1.

Moreover, in grip detection device for steering wheel 3 according to the present disclosure, capacitance sensor circuit 40a and mode switching circuit 40b are included in one control circuit 40, but capacitance sensor circuit 40a and mode switching circuit 40b may be each a separate independent circuit.

Those skilled in the art will readily appreciate that many modifications are possible in the above Embodiment without materially departing from the novel teachings and technical advantages of the present disclosure. Accordingly, all such modifications are intended to be included within the scope of the present disclosure.

### Further Information About Technical Background to this Application

The disclosure of the following patent application including specification, drawings, and claims is incorporated herein by reference in its entirety: Japanese Patent Application No. 2024-030176 filed on Feb. 29, 2024.

### Industrial Applicability

The grip detection device for the steering wheel according to the present disclosure is applicable to, for example, vehicle steering wheels.

1. A grip detection device for a steering wheel, the grip detection device comprising:
a first electrode arranged at a rim of the steering wheel;
a second electrode arranged at the rim and in a more inner layer of the steering wheel than the first electrode; and
a control circuit, wherein
the first electrode is wider in projected area than the second electrode,
the control circuit allows switching between:
a first mode in which the first electrode serves as a sensor electrode and the second electrode serves as a shield electrode; and
a second mode in which the first electrode serves as the shield electrode and the second electrode serves as the sensor electrode, and
the control circuit further:
obtains a first-mode capacitance detected by the first electrode serving as the sensor electrode in the first mode and a second-mode capacitance detected by the second electrode serving as the sensor electrode in the second mode; and
detects a grip on the steering wheel based on the first-mode capacitance and the second-mode capacitance.

2. The grip detection device according to claim 1, wherein
the control circuit includes a capacitance sensor circuit having: a sensor terminal that allows the first electrode to serve as the sensor electrode in the first mode and the second electrode to serve as the sensor electrode in the second mode; and a shield terminal that allows the second electrode to serve as the shield electrode in the first mode and the first electrode to serve as the shield electrode in the second mode,
the grip detection device further includes:
a first switch arranged between the sensor terminal and the second electrode;
a second switch arranged between the sensor terminal and the first electrode;
a third switch arranged between the shield terminal and the second electrode; and
a fourth switch arranged between the shield terminal and the first electrode, and
the control circuit:
turns on the second switch and the third switch and turns off remaining switches in the first mode; and
turns on the first switch and the fourth switch and turns off remaining switches in the second mode.

3. The grip detection device according to claim 1, wherein
the control circuit further allows switching to a third mode in which the second electrode acts as a heater.

4. The grip detection device according to claim 3, wherein
the second electrode, when acting as the heater, is connected to a battery that supplies power to a first end of the second electrode,
a second end of the second electrode is connectable to ground,
the grip detection device further includes:
a fifth switch arranged between the battery and the first end of the second electrode; and
a sixth switch arranged between the ground and the second end of the second electrode, and
the control circuit turns on the fifth switch and the sixth switch and turns off remaining switches in the third mode.

5. The grip detection device according to claim 1, wherein
the control circuit includes a mode switching circuit that switches modes at predetermined intervals, the modes including the first mode and the second mode.

6. The grip detection device according to claim 3, wherein
the control circuit includes a mode switching circuit that switches modes at predetermined intervals, the modes including the first mode, the second mode, and the third mode.

7. The grip detection device according to claim 2, wherein
the control circuit further allows switching to a third mode in which the second electrode acts as a heater.

8. The grip detection device according to claim 7, wherein
the second electrode, when acting as the heater, is connected to a battery that supplies power to a first end of the second electrode,
a second end of the second electrode is connectable to ground,
the grip detection device further includes:
a fifth switch arranged between the battery and the first end of the second electrode; and
a sixth switch arranged between the ground and the second end of the second electrode, and
the control circuit turns on the fifth switch and the sixth switch and turns off remaining switches in the third mode.
